(19) United States
(12) Patent Application Publication
(10) Pub. No.: US 2011/0254718 A1
(43) Pub. Date: Oct. 20, 2011

(54) INTEGRATOR AND DELTA-SIGMA MODULATOR INCLUDING THE SAME

(75) Inventors: Kazuo MATSUKAWA, Osaka (JP); Shiro DOSHO, Osaka (JP); Yosuke MITANI, Osaka (JP); Koji OBATA, Osaka (JP)

(73) Assignee: PANASONIC CORPORATION, Osaka (JP)

(21) Appl. No.: 13/166,518

(22) Filed: Jun. 22, 2011

Related U.S. Application Data
(63) Continuation of application No. PCT/JP2009/002870, filed on Jun. 23, 2009.

(30) Foreign Application Priority Data
Jan. 8, 2009 (JP) 2009-002377

(51) Int. Cl. H03M 3/00; G06G 7/18

(52) U.S. Cl. 341/143; 327/344

(57) ABSTRACT

An integrator is provided which can reduce a disturbance in the current waveform of a current DA converter in order to improve the SNR of a ΔΣ modulator, for example. The integrator includes an operational amplifier, and feedback paths provided in parallel between the output terminal and inverting input terminal of the operational amplifier. In one of the feedback paths, an integrating capacitor and at least one resistor are connected in series. In the other feedback path, a second integrating capacitor whose capacitance value is smaller than that of the integrating capacitor is provided.

### CROSS-REFERENCE TO RELATED APPLICATIONS

This is a continuation of PCT International Application PCT/JP2009/002870 filed on Jun. 23, 2009, which claims priority to Japanese Patent Application No. 2009-002377 filed on Jan. 8, 2009. The disclosures of these applications including the specifications, the drawings, and the claims are hereby incorporated by reference in their entirety.

### BACKGROUND

The present disclosure relates to integrators for use in loop filters of ΔΣ modulators etc.

A continuous-time ΔΣ modulator includes a loop filter. The loop filter is typically an active filter which employs an operational amplifier etc. FIG. 6A shows an example integrator used in the loop filter.

In actual circuits, the operational amplifier has a finite gain bandwidth, which affects characteristics of the integrator. Therefore, as indicated by a solid line in FIGS. 7A and 7B, the second pole occurs in a high frequency region in the gain characteristics and the phase characteristics.

There is a known technique of correcting the gain and phase characteristics by connecting a resistor in series to an integrating capacitor as shown in FIG. 6B (see, for example, F. Chen et al., “Compensation of Finite GBW Induced Performance Loss on a Fifth-order Continuous-time Sigma-Delta Modulator,” IEEE Canadian Conference on Electrical and Computer Engineering (CCECE 2006)). By using this technique, a zero point can be provided as indicated by a dashed line in FIGS. 7A and 7B, whereby the second pole can be canceled. In other words, band compensation is achieved.

However, the above technique has the following problem. It is assumed that a current digital-to-analog (DA) converter is used as a feedback DA converter (DAC) in the continuous-time ΔΣ modulator. In this case, because the current DA converter is not an ideal current source and has a finite output resistance, if the current value of the current DA converter changes due to the resistor connected in series to the integrating capacitor, the transient response is disturbed. Therefore, as indicated by a solid line in FIG. 8, ringing occurs in the current change. The disturbance of the current waveform causes an error in calculation of the continuous-time ΔΣ modulator, leading to a degradation in the signal-to-noise ratio (SNR). In other words, such a problem arises in conventional band compensation integrators, such as that shown in FIG. 6B.

### SUMMARY

The present disclosure describes implementations of an integrator which can reduce a current waveform disturbance in a current DA converter to improve the SNR of a ΔΣ modulator, for example.

An integrator according to an aspect of the present disclosure includes an operational amplifier, a voltage input terminal connected via an input resistor to an inverting input terminal of the operational amplifier, and a first and a second feedback path connected together in parallel between an output terminal and the inverting input terminal of the operational amplifier. In the first feedback path, a first integrating capacitor and at least one first resistor are connected together in series. In the second feedback path, a second integrating capacitor having a smaller capacitance value than that of the first integrating capacitor is provided.

According to this aspect of the present disclosure, in the first feedback path, the first resistor is connected in series to the first integrating capacitor, whereby, in characteristics of the integrator, a zero point is generated to cancel the second pole which occurs due to the gain bandwidth of the operational amplifier. Also, in the second feedback path provided in parallel with the first feedback path, the second integrating capacitor whose capacitance value is smaller than that of the first integrating capacitor is provided, whereby, in characteristics of the integrator, the third pole is generated at a higher frequency point than the zero point. As a result, the gain characteristics and phase characteristics of the integrator are improved as indicated by a dot-dash line in FIGS. 7A and 7B. When the output of the current DA converter is connected to the inverting input terminal of the operational amplifier, the ringing of the output current waveform of the current DA converter is reduced as indicated by a dashed line in FIG. 8.

In the integrator of this aspect of the present disclosure, the capacitance value of the second integrating capacitor is preferably within the range of 5-30% of the capacitance value of the first integrating capacitor.

In the integrator of this aspect of the present disclosure, in the second feedback path, at least one second resistor is preferably connected in series to the second integrating capacitor, and the product of the capacitance value of the first integrating capacitor and the resistance value of the first resistor is preferably greater than the product of the capacitance value of the second integrating capacitor and the resistance value of the second resistor.

In the integrator of this aspect of the present disclosure, an output of the current DA converter is preferably connected to the inverting input terminal of the operational amplifier.

A ΔΣ modulator with a loop filter according to another aspect of the present disclosure includes the integrator of the present disclosure in the loop filter. An output of the current DA converter is connected to the inverting input terminal of the operational amplifier. An output of the ΔΣ modulator is supplied as an input to the current DA converter.

According to this aspect of the present disclosure, high-precision calculation can be achieved, thereby improving the SNR.

As described above, according to the present disclosure, characteristics of the integrator can be improved, whereby the ringing of the transient response waveform of the current DA converter can be reduced, and the SNR of the ΔΣ modulator can be improved.

### BRIEF DESCRIPTION OF THE DRAWINGS

FIG. 1 is a circuit diagram showing a configuration of an integrator according to an embodiment.

FIG. 2 is a circuit diagram showing a configuration of a differential integrator according to the embodiment.

FIGS. 3A and 3B are diagrams showing configurations of integrators according to variations.

FIG. 4 is a diagram showing an example configuration of a differential current DA converter connected to the integrator.

FIG. 5 is a diagram showing an example configuration of a ΔΣ modulator including the integrator of the embodiment.

FIG. 6A is a diagram showing a conventional integrator.

FIG. 6B is a diagram showing a conventional band compensation integrator.

FIGS. 7A and 7B are graphs showing characteristics of integrators.

FIG. 8 is a graph showing a current waveform of a current DA converter.

### DETAILED DESCRIPTION

Embodiments of the present disclosure will be described in detail hereinafter with reference to the accompanying drawings.

FIG. 1 is a circuit diagram showing a configuration of an integrator according to an embodiment. In FIG. 1, the integrator includes an input resistor (R1) 100, a voltage input terminal 101, an operational amplifier 102, and a current DA converter 103. The voltage input terminal 101 is connected via the input resistor 100 to the inverting input terminal of the operational amplifier 102. The output of the current DA converter 103 is also connected to the inverting input terminal of the operational amplifier 102. A first and a second feedback path F1 and F2 are provided between the output terminal and the inverting input terminal of the operational amplifier 102. In the first feedback path F1, a first integrating capacitor 105 (C2) and a first resistor 107 (R3) are connected together in series. In the second feedback path F2, a second integrating capacitor 106 (C3) is provided. The capacitance value C3 of the second integrating capacitor 106 is smaller than the capacitance value C2 of the first integrating capacitor 105. The capacitance value C3 of the second integrating capacitor 106 is preferably within the range of 5-30% of the capacitance value C2 of the first integrating capacitor 105.

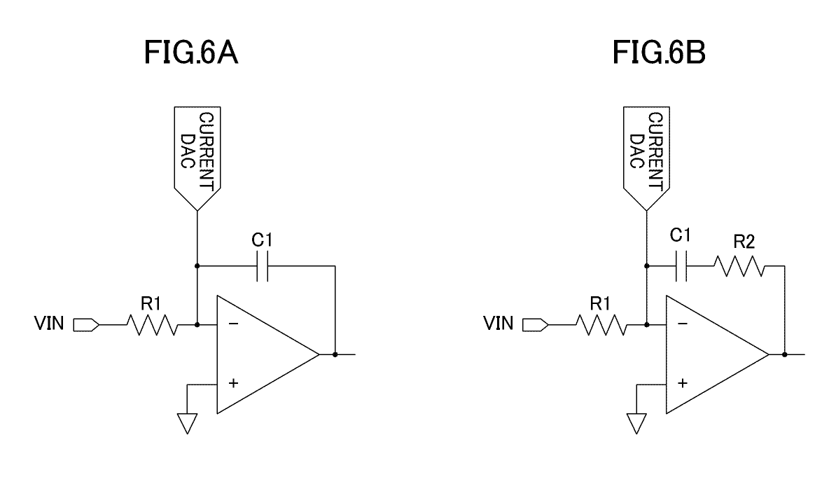

In the configuration of FIG. 1, the capacitance values C2 and C3 and the resistance value R3 may be determined to satisfy the following conditions, as compared to the configuration of FIG. 6B:

C2=(1−r)·C1

C3=r·C1

R3=R2/(1−r)

where r is preferably about 0.05-0.25.

In the second feedback path F2, a second resistor (R4) may be connected in series to the second integrating capacitor 106. In this case, the product of the capacitance value C2 of the first integrating capacitor 105 and the resistance value R3 of the first resistor 107 is preferably greater than the product of the capacitance value C3 of the second integrating capacitor 106 and the resistance value R4 of the second resistor, i.e.,

C2·R3>C3·R4.

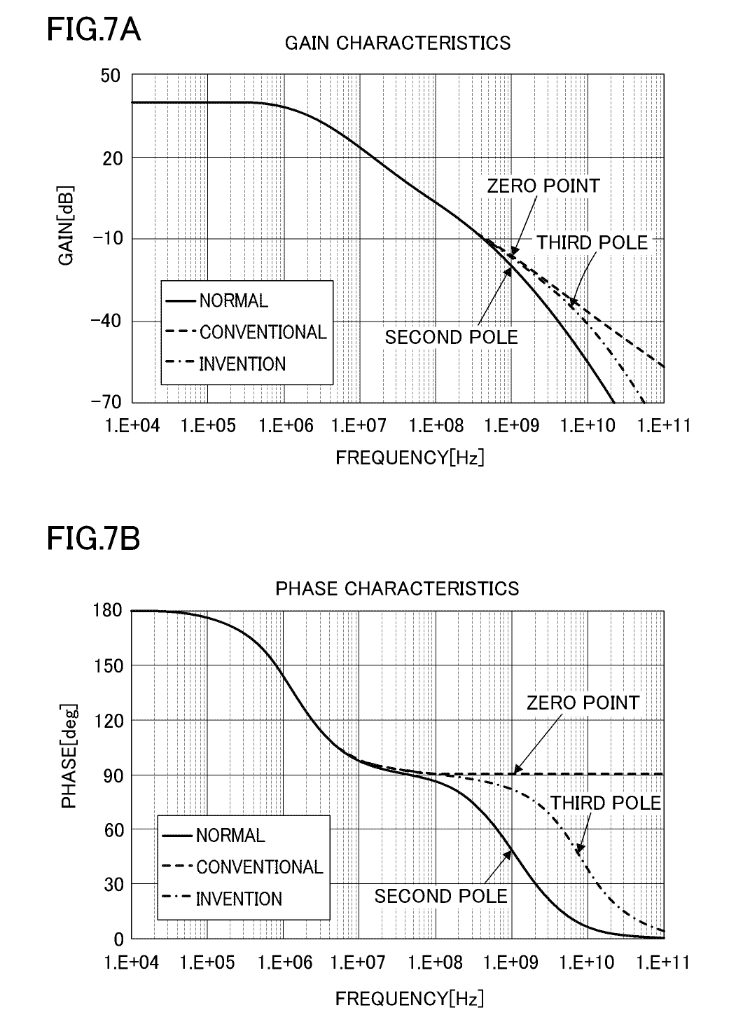

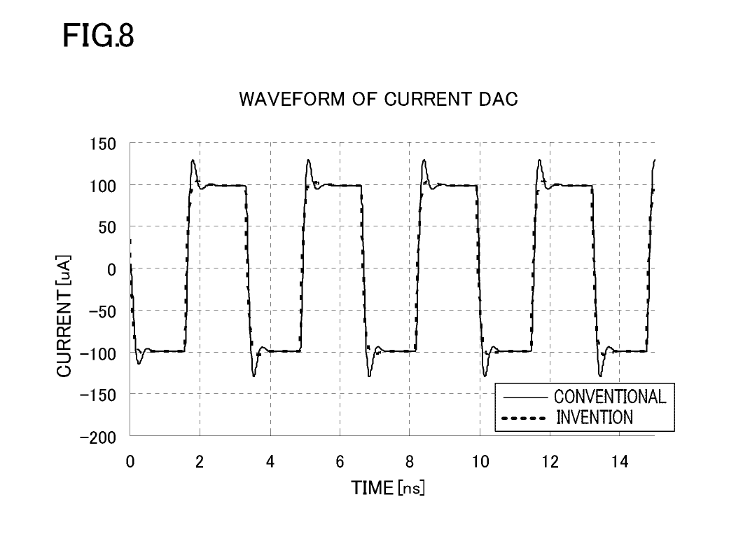

Because the first resistor 107 is connected in series to the first integrating capacitor 105 in the first feedback path F1, a zero point can be formed in the characteristics of the integrator so that the second pole occurring due to the bandwidth of the operational amplifier 102 is canceled. Moreover, because the second feedback path F2 is provided in parallel with the first feedback path F1, and the second integrating capacitor 106 whose capacitance value is smaller than that of the first integrating capacitor 105 is provided in the second feedback path F2, the third pole can be formed at a higher frequency point than the zero point. As a result, as indicated by a dot-dash line in FIGS. 7A and 7B, the gain characteristics and the phase characteristics are improved. Also, as indicated by a dashed line in FIG. 8, the ringing of the output current waveform of the current DA converter 103 can be reduced.

Note that, in the first feedback path F1, a plurality of resistors may be connected in series to the integrating capacitor 105.

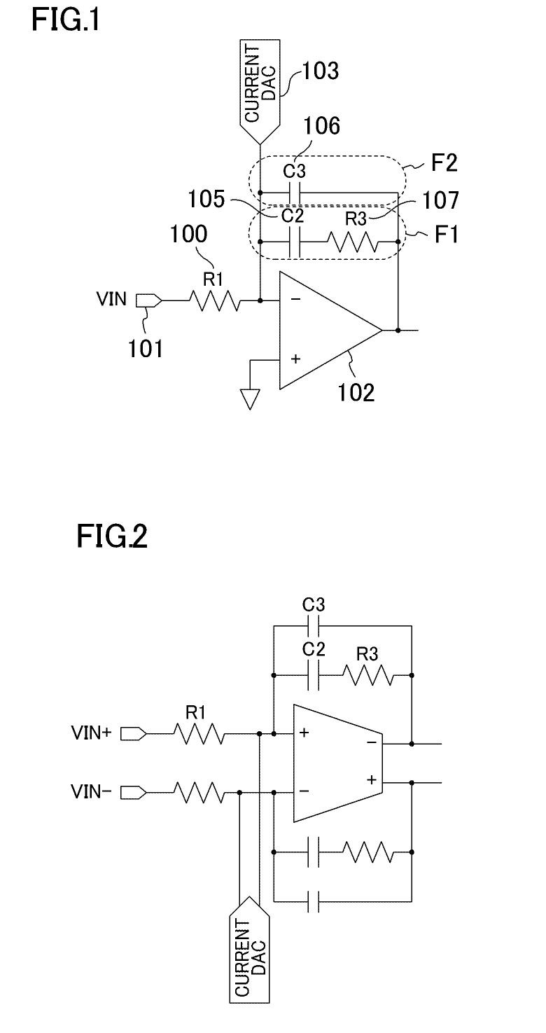

FIG. 2 is a circuit diagram showing a configuration of a differential integrator according to this embodiment. The configuration of FIG. 2 can provide advantages similar to those of FIG. 1.

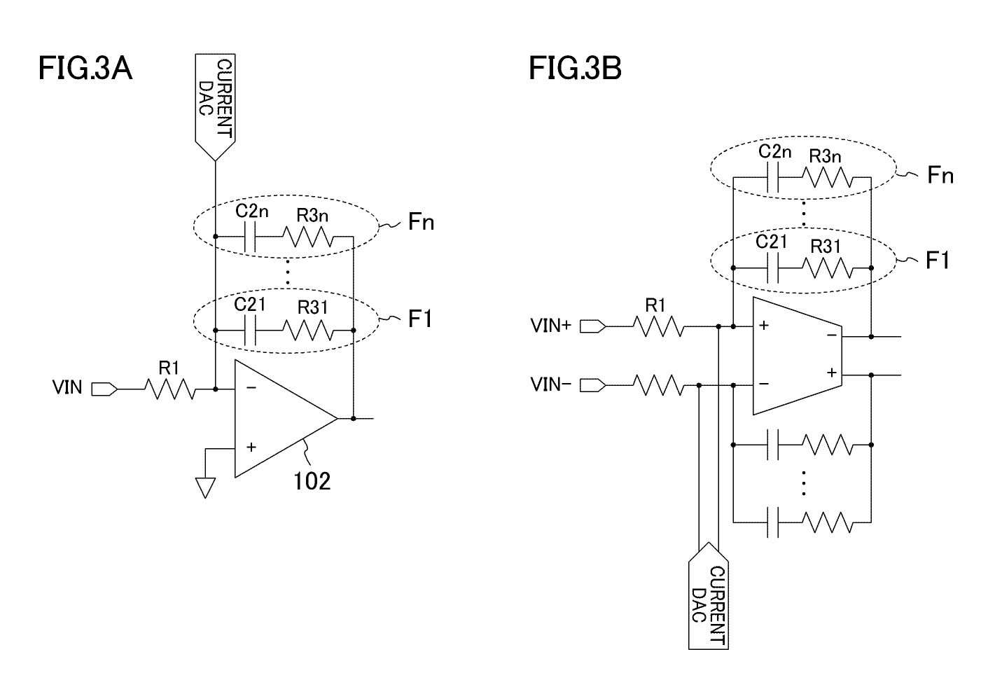

As shown in FIG. 3A, three or more feedback paths F1-Fn may be provided between the output terminal and inverting input terminal of the operational amplifier 102. In this configuration, if the first feedback path F1 and any of the other feedback paths F2-Fn satisfy the aforementioned conditions, advantages similar to those described above are obtained. FIG. 3B shows another example configuration of the differential integrator.

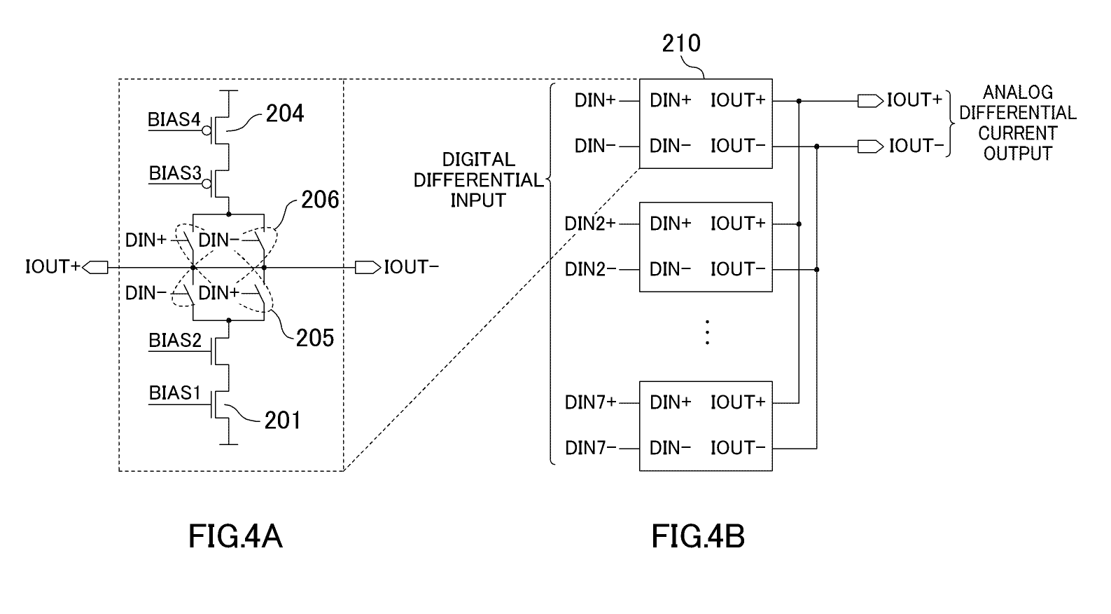

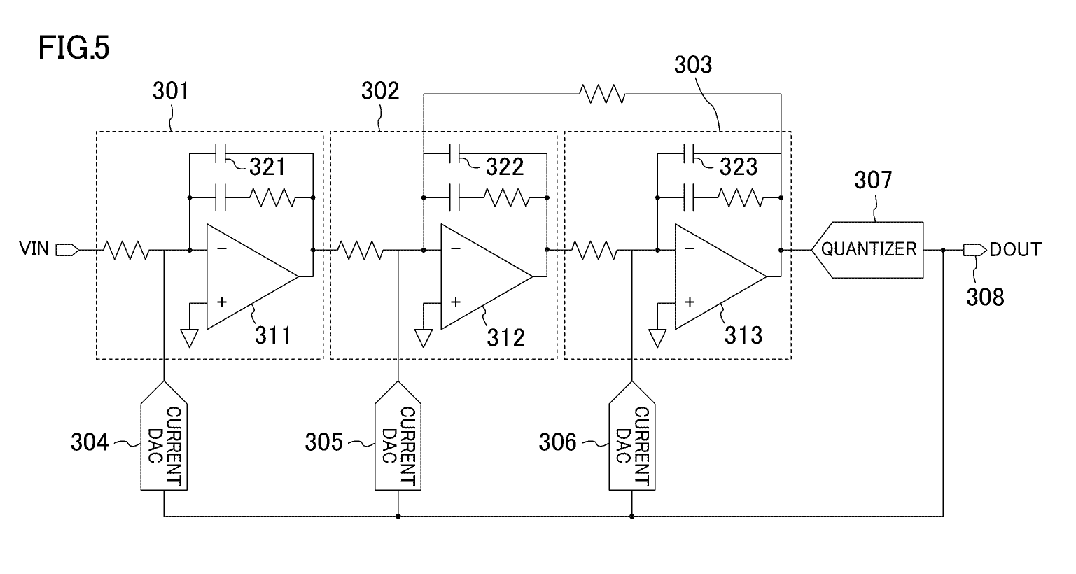

FIG. 4 shows an example configuration of a differential current DA converter connected to the integrator of this embodiment. A portion (A) of FIG. 4 shows an internal configuration of a cell included in the current DA converter, and a portion (B) of FIG. 4 shows an entire configuration of the current DA converter. As shown in the portion (A) of FIG. 4, the cell 210 includes a current source 201 including an NMOS transistor, a current source 204 including a PMOS transistor, and switches 205 and 206 provided between the current sources 201 and 204. The switch 205 is turned on/off based on a digital input DIN+, and the switch 206 is turned on/off based on an inverted digital input DIN−. Analog differential currents IOUT+ and IOUT− are output from a connection point of the switches 205 and 206. Also, as shown in the portion (B) of FIG. 4, in the entire current DA converter, a plurality of the cells 210 of FIG. 4A are connected together in parallel, and the analog differential currents IOUT+ and IOUT− are controlled and output based on the digital differential inputs DIN+ and DIN−.

FIG. 5 shows an example configuration of a ΔΣ modulator which employs the integrator of this embodiment. The ΔΣ modulator of FIG. 5 includes integrators 301, 302, and 303 of this embodiment in a loop filter thereof. Current DA converters 304, 305, and 306 are connected to the inverting input terminals of the operational amplifiers 311, 312, and 313 in the integrators 301, 302, and 303, respectively. A quantizer 307 is provided between the integrator 303 and the output terminal 308. The output of the integrator 303 is connected via a resistor to the integrator 302. The integrators 302 and 303 function as a filer circuit. Note that, in the configuration of FIG. 5, the three integrators 301, 302, and 303 are connected in cascade in the integration circuit section, but the second integrator 302 is not necessarily required. The current DA converters 305 and 306 may be removed.

The output of the quantizer 307 is connected to the inputs of the current DA converters 304, 305, and 306. The output DOUT of the ΔΣ modulator is supplied as an input to the current DA converters 304, 305, and 306. In other words, the output DOUT is fed back via the current DA converters 304, 305, and 306 to the integrators 301, 302, and 303. In this case, ringing is reduced by the integrating capacitors 321, 322, and 323 in the integrators 301, 302, and 303.

Thus, by utilizing the integrator of this embodiment in a ΔΣ modulator, high-precision feedback can be achieved by the current DA converter.

In the integrator of this embodiment, a zero point is generated by adding a resistor to the first feedback path, to cancel the second pole. When the integrator of this embodiment is employed as a loop filter in a ΔΣ modulator, then if the resistance value of the resistor is appropriately selected, a zero point can be generated at any arbitrary position to change the transfer function of the filer.

According to the present disclosure, characteristics of an integrator are improved. Therefore, the present disclosure is useful for high-speed operation of a ΔΣ modulator, for example.

What is claimed is:

1. An integrator comprising:
an operational amplifier;
a voltage input terminal connected via an input resistor to an inverting input terminal of the operational amplifier; and
a first and a second feedback path connected together in parallel between an output terminal and the inverting input terminal of the operational amplifier,
wherein
in the first feedback path, a first integrating capacitor and at least one first resistor are connected together in series, and
in the second feedback path, a second integrating capacitor having a smaller capacitance value than that of the first integrating capacitor is provided.

2. The integrator of claim 1, wherein
the capacitance value of the second integrating capacitor is within the range of 5-30% of the capacitance value of the first integrating capacitor.

3. The integrator of claim 1, wherein
in the second feedback path, at least one second resistor is connected in series to the second integrating capacitor, and
the product of the capacitance value of the first integrating capacitor and the resistance value of the first resistor is greater than the product of the capacitance value of the second integrating capacitor and the resistance value of the second resistor.

4. The integrator of claim 1, wherein
an output of a current DA converter is connected to the inverting input terminal of the operational amplifier.

5. A ΔΣ modulator with a loop filter, comprising:
the integrator of claim 4 in the loop filter,
wherein
an output of the ΔΣ modulator is supplied as an input to the current DA converter.

6. A ΔΣ modulator comprising:
an integration circuit section configured to receive a signal and output an integrated signal;
a quantizer configured to receive an output signal of the integration circuit section and output a quantized signal;
a current DA converter configured to receive the quantized signal and output a current signal,
wherein
the integration circuit section includes
an integrator including
an operational amplifier,
a signal input terminal connected via an input resistor to an inverting input terminal of the operational amplifier,
a first feedback path including a first resistor and a first capacitor connected together in series between an output terminal and the inverting input terminal of the operational amplifier, and
a second feedback path including a second capacitor connected between the output terminal and the inverting input terminal of the operational amplifier, and
an output signal of the current DA converter is supplied to the inverting input terminal of the operational amplifier.

7. The ΔΣ modulator of claim 6, wherein
the integration circuit section further includes a filer circuit configured to receive an output signal of the integrator, and
an output signal of the filer circuit is supplied to the quantizer.

8. The ΔΣ modulator of claim 6, wherein
the capacitance value of the second capacitor is smaller than that of the first capacitor.

9. A ΔΣ modulator comprising:
a first integrator;
a second integrator;
a quantizer configured to receive an output signal of the second integrator and output a quantized signal; and
a current DA converter configured to receive the quantized signal and output a current signal,
wherein
the first integrator includes
a first operational amplifier,
a first signal input terminal connected via an input resistor to an inverting input terminal of the first operational amplifier,
a first feedback path including a first resistor and a first capacitor connected together in series between an output terminal and the inverting input terminal of the first operational amplifier, and
a second feedback path including a second capacitor connected between the output terminal and the inverting input terminal of the first operational amplifier,
the first integrator integrates a signal supplied to the first signal input terminal and outputs the integrated signal,
the second integrator includes
a second operational amplifier,
a second signal input terminal connected via an input resistor to an inverting input terminal of the second operational amplifier, and connected to an output terminal of the first integrator,
a third feedback path including a second resistor and a third capacitor connected together in series between an output terminal and the inverting input terminal of the second operational amplifier, and
a fourth feedback path including a fourth capacitor connected between the output terminal and the inverting input terminal of the second operational amplifier,
the second integrator integrates a signal supplied to the second signal input terminal and outputs the integrated signal, and
an output signal of the current DA converter is supplied to the inverting input terminal of the first operational amplifier.

10. The ΔΣ modulator of claim 9, wherein
the capacitance value of the second capacitor is smaller than that of the first capacitor.
